(19) United States
(12) Patent Application Publication
(10) Pub. No.: US 2008/0157792 A1
(43) Pub. Date: Jul. 3, 2008

(54) Probe Card and Method of Manufacturing the Same

(76) Inventor: Oug-Ki Lee, Seoul (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 11/908,996

(22) PCT Filed: Mar. 20, 2006
(86) PCT No.: PCT/KR06/01008

§ 371 Date: Sep. 18, 2007

(30) Foreign Application Priority Data
Mar. 21, 2005 (KR) 10-2005-0023309

(51) Int. Cl. G01R 1/067; G01R 31/02

(52) U.S. Cl. 324/754; 29/825

(57) ABSTRACT

A probe card includes a first micro probe head (MPH), a second MPH, and needles. The first MPH includes first conductive traces into which a test signal for testing an object having outer terminals is inputted. The second MPH includes second conductive traces electrically connected to the first conductive traces, respectively, and arranged corresponding to the outer terminals. The second MPH is detachably combined with the first MPH. The needles are electrically connected to the second conductive traces, respectively, to make contact with the outer terminals, respectively. Thus, only the second MPH may be replaced with a new one in accordance with alterations to the object so that time and costs for manufacturing the probe card may be reduced.

### TECHNICAL FIELD

The present invention relates to a probe card and a method of manufacturing the same. More particularly, the present invention relates to a probe card that is used for testing electrical characteristics of an electronic device, such as a semiconductor device, and a method of manufacturing the probe card.

### BACKGROUND ART

In general, after a plurality of processes is carried out on a semiconductor substrate to form semiconductor devices, a probing test is performed on the semiconductor devices to select a normal semiconductor device among the manufactured semiconductor devices. A packaging process is then carried out on the normal semiconductor devices to form semiconductor packages.

In the probing test, needles of a probe card respectively make contact with outer terminals of the semiconductor device, such as an electrode pad. A tester provides the outer terminals with a test signal through the needles. The tester receives electrical signals outputted from the outer terminals. The tester determines the normality of the semiconductor device based on the received electrical signals.

The probe card used for the probing test includes a printed circuit board (PCB) having circuits through which the test signal flows, a micro probe head (MPH) combined with a bottom face of the PCB and electrically connected to the circuits, and the needles electrically connected to the MPH and making contact with the outer terminals of the semiconductor device.

FIG. 1 is a cross-sectional view illustrating a conventional probe card and FIG. 2 is an enlarged cross-sectional view illustrating a PCB and an MPH in FIG. 1.

Referring to FIGS. 1 and 2, a conventional probe card 100 includes a PCB 102, an MPH 106 and needles 108.

The PCB 102 includes a plurality of electrical contacts 130 that are electrically connected to a tester 120 for generating a test current through electrical connections 122. Further, the PCB 102 includes conductive traces 150 extending from the electrical contacts 130.

The MPH 106 is arranged under the PCB 102. The MPH 106 includes conductive traces 154 electrically connected to the conductive traces 150 of the PCB 102 through conductive members 152.

The needles 108 are connected to the conductive traces 154 of the MPH 106. The needles 108 respectively make contact with electrode pads 162 of a semiconductor device 160.

Here, in order to allow the needles 108 to make contact with the electrode pads 162, respectively, a number and arrangement of the conductive traces 154 of the MPH 106 must correspond to those of the electrode pads 162 of the semiconductor device 160.

However, the MPH of the conventional probe card is a single part. Thus, to test a new object including a different number and/or an arrangement of outer terminals, it is necessarily required to replace the MPH with a new MPH that includes conductive traces corresponding to the outer terminals of the new object. As a result, to test electrical characteristics of the new object, it is additionally required to manufacture the new MPH.

Particularly, as the number of the semiconductor devices obtained from a single semiconductor substrate has been increased, the MPH for simultaneously testing the semiconductor devices may have a multi-layered structure, for example, a twenty-layered structure. In contrast, the tester may be standardized so that the electrical connections of the tester through which the test signal flows may not be changed regardless of a number and/or an arrangement of outer terminals of the object. Therefore, an upper layer of the MPH electrically connected to the tester may be still used regardless of the number and the arrangement of the outer terminals of the object. However, as described above, since the conventional MPH is the unseparated single part, it is required to replace the MPH with the new MPH in accordance with changes of the object.

Further, the single MPH is manufactured by sequentially stacking the twenty layers. Thus, the conventional MPH may have poor flatness. When the object is tested using the MPH having the poor flatness, all of the needles may not make contact with the outer terminals of the object. As a result, the test process using the MPH having the poor flatness may have low reliability.

Furthermore, a time for manufacturing the MPH takes up no less than about 70% of the total time for manufacturing the probe card. Thus, costs and time for manufacturing a new probe card may be remarkably increased due to the manufacture of the new MPH. As a result, a forwarding time of the semiconductor device that has passed the electrical test may be delayed.

### DISCLOSURE OF THE INVENTION

### Technical Problem

Example embodiments of the present invention provide a probe card that is partially replaced with a new one in accordance with alterations to an object.

Example embodiments of the present invention also provide a method of manufacturing the above-mentioned probe card.

### Technical Solution

A probe card in accordance with one aspect of the present invention includes a first micro probe head (MPH), a second MPH, and needles. The first MPH includes first conductive traces into which a test signal for testing an object having outer terminals is inputted. The second MPH includes second conductive traces electrically connected to the first conductive traces, respectively, and arranged corresponding to the outer terminals. The second MPH is detachably combined with the first MPH. The needles are electrically connected to the second conductive traces, respectively, to make contact with the outer terminals, respectively.

In a method of manufacturing a probe card in accordance with another aspect of the present invention, a first MPH including first conductive traces into which a test signal for testing an object having outer terminals is inputted is prepared. A second MPH having second conductive traces that correspond to the outer terminals is prepared. The second MPH is detachably combined with the first MPH to electrically connect the first conductive traces to the second conductive traces, respectively. Needles for making contact with the outer terminals, respectively, are electrically connected to the second conductive traces, respectively.

### Effect of the Invention

According to the present invention, the MPH includes the two detachable heads so that only the second MPH may be replaced with a new one in accordance with alterations to the object. Thus, time and costs for manufacturing the probe card may be reduced. Further, when the probe card has a multi-layered structure, it is not required to entirely replace the probe card having the multi-layered structure with a new one. As a result, the probe card having the multi-layered structure may have good flatness.

### BRIEF DESCRIPTION OF THE DRAWINGS

The above and other features and advantages of the invention will become readily apparent by reference to the following detailed description when considered in conjunction with the accompanying drawings wherein:

FIG. 1 is a cross-sectional view illustrating a conventional probe card;

FIG. 2 is an enlarged cross-sectional view illustrating a printed circuit board (PCB) and an MPH (MPH) in FIG. 1;

FIG. 3 is an exploded cross-sectional view illustrating a probe card in accordance with a first example embodiment of the present invention;

FIG. 4 is a combined cross-sectional view illustrating the probe card in FIG. 3;

FIG. 5 is a cross-sectional view illustrating a probe card in accordance with a second example embodiment of the present invention;

FIG. 6 is a plan view illustrating a first MPH in FIG. 5;

FIGS. 7 and 8 are cross-sectional views illustrating a horizontal level adjustment of the probe card in FIG. 5;

FIG. 9 is a flow chart illustrating a method of manufacturing a probe card in accordance with a third example embodiment of the present invention; and

FIG. 10 is a flow chart illustrating a process for forming needles in the method of FIG. 9.

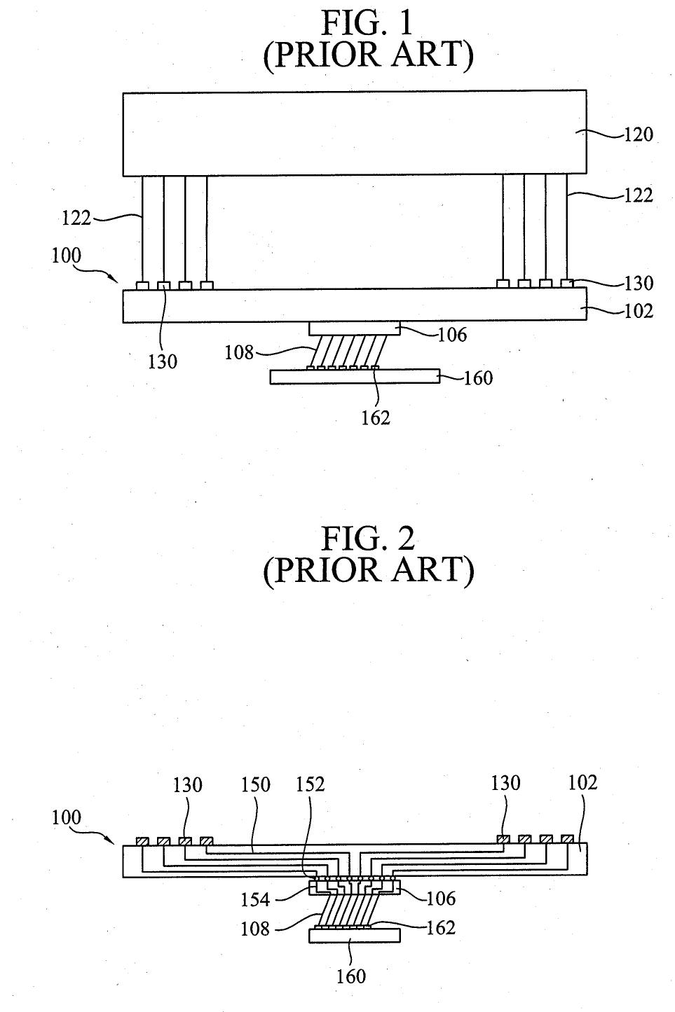

### BEST MODE FOR CARRYING OUT THE INVENTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### EMBODIMENT 1

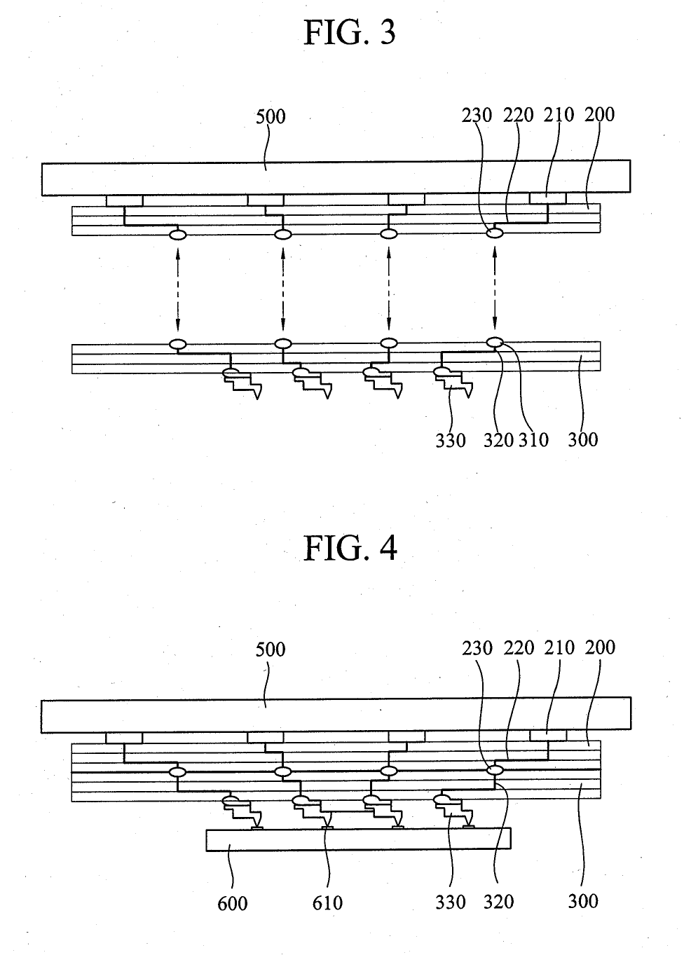

FIG. 3 is an exploded cross-sectional view illustrating a probe card in accordance with a first example embodiment of the present invention and FIG. 4 is a combined cross-sectional view illustrating the probe card in FIG. 3.

Referring to FIGS. 3 and 4, a probe card of this example embodiment includes a printed circuit board (PCB) 500, a first micro probe head (MPH) 200, a second MPH 300 and needles 330.

The PCB 500 includes a circuit (not shown) for receiving a test signal, which is used for testing electrical characteristics of an object such as a semiconductor device 600 that has electrode pads 610 as outer terminals, from a tester (not shown).

The first MPH 200 is combined with a bottom face of the PCB 500. The first MPH 200 has a multi-layered structure. Further, the first MPH 200 includes an insulation material such as ceramic. Electrical contacts 210 electrically connected to the circuit of the PCB 500 are formed on an upper face of the first MPH 200. The first MPH 200 further includes a plurality of first conductive traces 220 electrically connected to the electrical contacts 210, respectively. The first conductive traces 220 are exposed through a bottom face of the first MPH 200.

Here, the first conductive traces 220 have a number and arrangement corresponding to those of the circuit of the PCB 500. Since the circuit of the PCB 500 corresponds to a standardized circuit of the tester, the first conductive traces 220 may be standardized. Thus, although the semiconductor device 600 is replaced with a new one, it is not required to replace the PCB 500 and the first MPH 200 with new ones.

The second MPH 300 is detachably combined with a bottom face of the first MPH 200. The second MPH 300 has a multi-layered structure. Further, the second MPH 300 includes an insulation material such as ceramic. Here, the insulation material of the second MPH 300 may be substantially the same as that of the first MPH 200. The second MPH 300 includes second conductive traces 320 electrically connected to the first conductive traces 220, respectively. The second conductive traces 320 are exposed through a bottom face of the second MPH 300.

Here, in order to allow the needles 330 to make contact with the electrode pads 610, respectively, it is necessarily required to provide the second conductive traces 320 with the number and the arrangement corresponding to those of the electrode pads 610 of the semiconductor device 600. That is, when the semiconductor device 600 is changed into a new one, it is required to manufacture a new second MPH having a new number and arrangement of second conductive traces corresponding to those of electrode pads of the new semiconductor device.

Therefore, according to this example embodiment, when the semiconductor device 600 is changed into a new one, only the second MPH 300 is replaced with a new one without replacing the first MPH 200 with a new one.

The first and second MPHs 200 and 300 are detachably combined with each other using a combining member. In this example embodiment, the combining member includes conductive members 230 interposed between the first and second conductive traces 220 and 320. An example of the conductive members 230 includes an elastic metal such as solder. When the solder is used for the conductive members 230, the first and second conductive traces 220 and 320 are detachably combined with each other by a soldering process. On the contrary, to detach the second MPH 300 from the first MPH 200, the solder is removed to disconnect the first and second conductive traces 220 and 320.

The needles 330 are electrically connected to the second conductive traces 320 exposed through the bottom face of the second MPH 300, respectively. Each of the needles 330 makes contact with each of the electrode pads 610 of the semiconductor device 600. Thus, the number and arrangement of needles 330 correspond to those of the electrode pads 610. Here, the needles 330 are positioned on the second conductive traces 320. When the number and the arrangement of the second conductive traces 320 correspond to those of the electrode pads 610, the number and the arrangement of the needles 330 automatically correspond to those of the electrode pads 610.

The test signal generated from the tester is provided to the electrodes pads 610 through the PCB 500, the first conductive traces 220, the second conductive traces 320 and the needles 330 to test the electrical characteristics of the semiconductor device 600.

According to this example embodiment, the MPH includes the two detachable heads. Thus, when the object is changed into a new one, only the second MPH may be replaced with a new one without replacing the standardized first MPH with a new one. Thus, only the new second MPH corresponding to the new object may be manufactured without manufacturing the entire probe card. As a result, time and costs for manufacturing the probe card may be reduced.

Further, since only the second MPH is replaced with a new one, the probe card having the multi-layered structure may have good flatness. Therefore, the needles may accurately make contact with the outer terminals so that a test process using the probe card may have improved reliability.

### EMBODIMENT 2

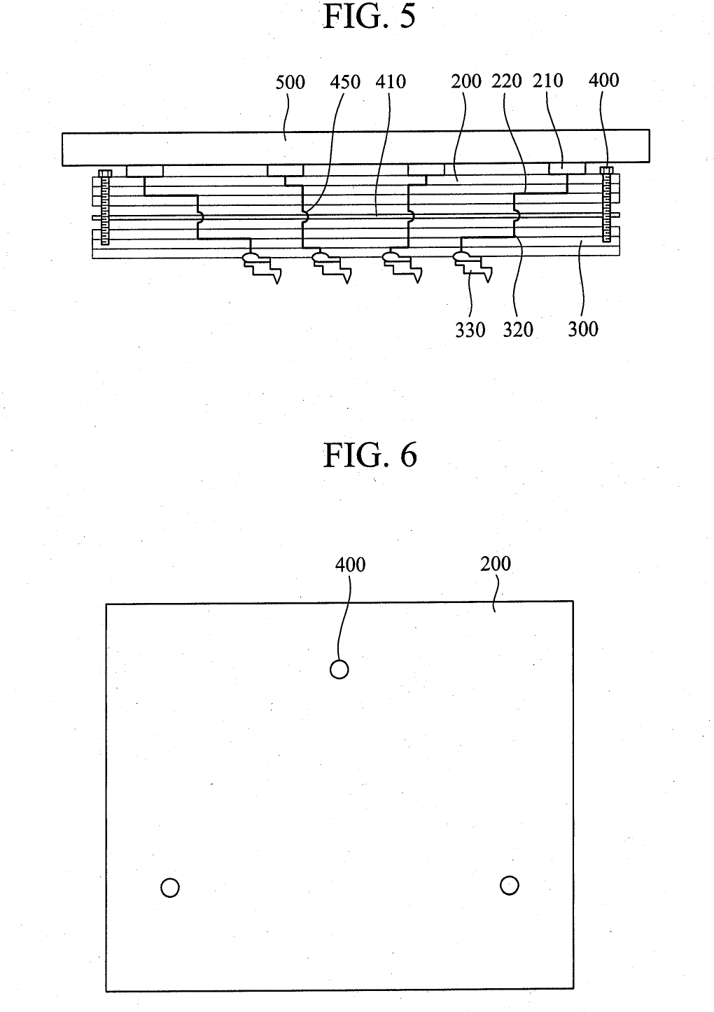

FIG. 5 is a cross-sectional view illustrating a probe card in accordance with a second example embodiment of the present invention, FIG. 6 is a plan view illustrating a first MPH in FIG. 5 and FIGS. 7 and 8 are cross-sectional views illustrating a horizontal level adjustment of the probe card in FIG. 5.

A probe card of this example embodiment includes elements substantially the same as those of the probe card in Embodiment 1 except for a combination structure between the first and second MPHs. Thus, the same reference numerals refer to the same elements and any further illustrations with respect to the same elements are omitted herein for brevity.

Referring to FIG. 5, the first MPH 200 and the second MPH 300 are combined with each other using a screw 400 as a combining member. The screw 400 is inserted into the first MPH 200 and the second MPH 300 in a vertical direction from an upper face of the first MPH 200.

Conductive members 450 are interposed between the first conductive traces 220 and the second conductive traces 320. The conductive members 450 electrically make contact with the first and second conductive traces 220 and 320 differently from the combination structure in Embodiment 1. A supporting plate 410 for receiving the conductive members 450 is interposed between the first MPH 200 and the second MPH 300. Thus, the screw 400 is also inserted into the supporting plate 410.

Here, the screw 400 functions so as to adjust horizontal levels of the first MPH 200 and the second MPH 300, as well as to detachably combine the second MPH 300 with the first MPH 200.

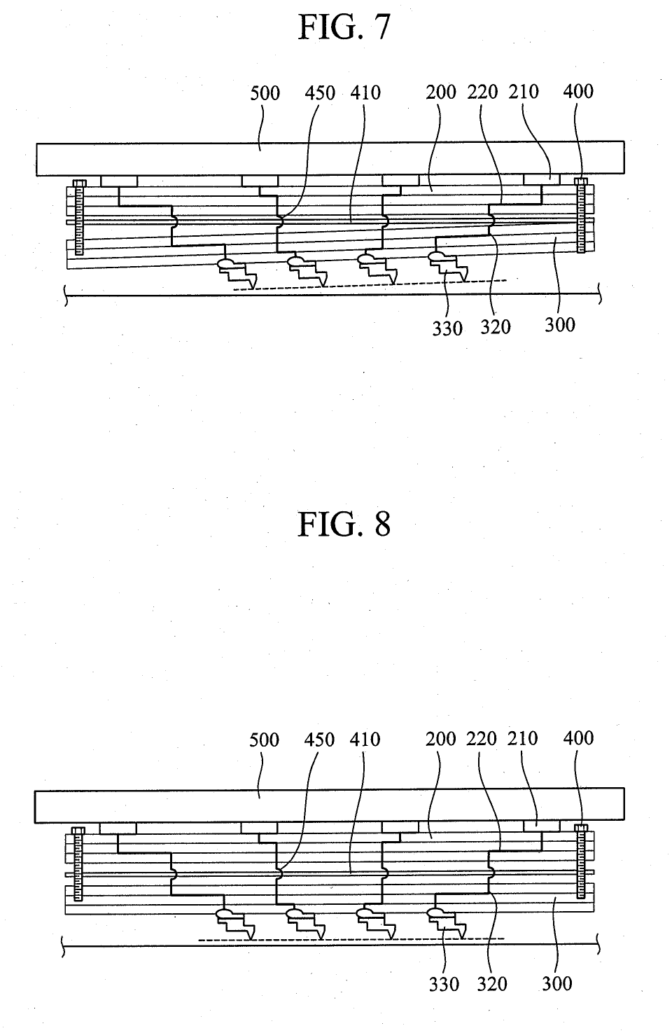

As shown in FIG. 6, the three screws 400 are inserted into three edge portions of the first and second MPHs 200 and 300. For example, as shown in FIG. 7, when the second MPH 300 is inclined relative to a horizontal plane of the object, needles 330 placed on a plane higher than the horizontal plane may not make contact with the electrode pad. In this case, a screw 400 adjacent to the needles 330 on the plane descends to provide the second MPH 300 with the horizontal level substantially parallel with the horizontal plane of the object, as shown in FIG. 8,

### EMBODIMENT 3

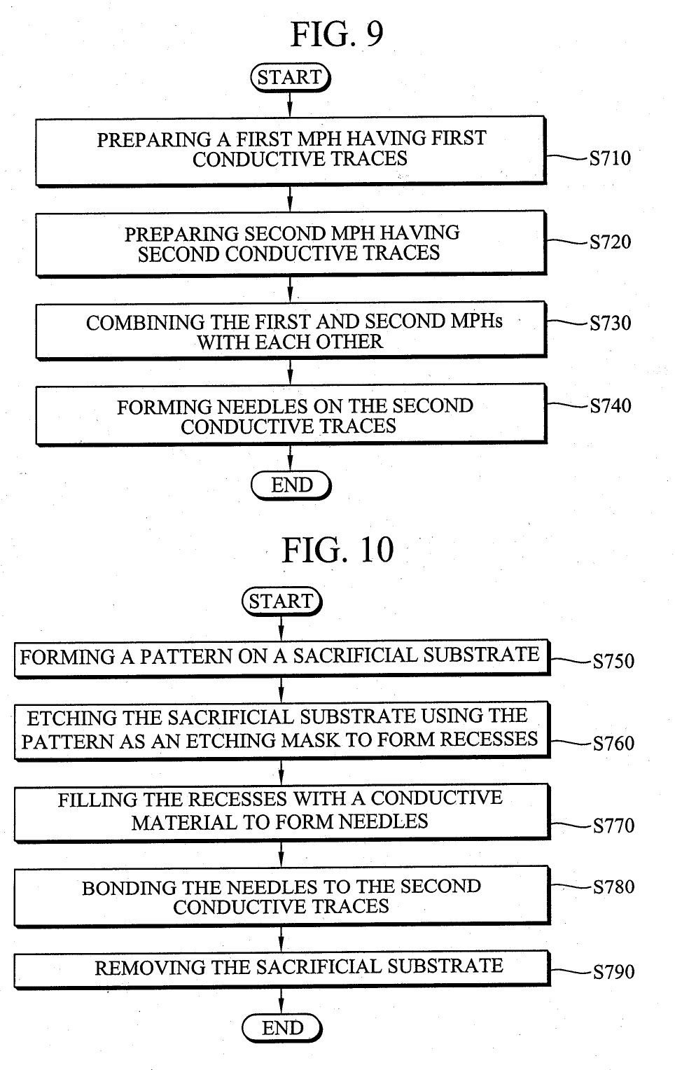

FIG. 9 is a flow chart illustrating a method of manufacturing a probe card in accordance with a third example embodiment of the present invention; and FIG. 10 is a flow chart illustrating a process for forming needles in the method of FIG. 9.

Referring to FIG. 9, in step S710, the first MPH having the first conductive traces is prepared. Particularly, a metal layer is formed on a first insulation layer having a hole to fill up the hole with the metal layer. The metal layer is patterned to form first sub-traces. A process substantially the same as or similar to that performed on the first insulation layer is carried out on a second insulation layer to form second sub-traces. The above-mentioned process is repeatedly carried out on a plurality of insulation layers in accordance with a number of stacked insulation layers in the desired first MPH. The insulation layers are sequentially stacked to electrically connect the sub-traces to each other, thereby completing the first MPH having a multi-layered structure. Here, the first conductive traces have an arrangement substantially the same as that of a standardized circuit in a PCB.

In step S720, a process substantially the same as that forming the first MPH is carried out to form the second MPH having the second conductive traces. Here, the number and arrangement of the second conductive traces correspond to those of the outer terminals of the object. That is, although the number and arrangement of the first conductive traces do not correspond to those of the object, it is necessarily required to provide the second conductive traces with the number and the arrangement corresponding to those of the object. Thus, when the object is changed into a new one, only the second MPH is replaced with a new one without replacing the first MPH with a new one.

In step S730, the first and second MPHs are detachably combined with each other to electrically connect the first conductive traces to the second conductive traces, respectively.

Here, conductive members such as solder may be interposed between the first and second conductive traces. A soldering process is performed on the conductive members to combine the first and second MPHs with each other. Alternatively, the screws may be inserted into the edge portions of the first and second MPHs to detachably combine the first and second MPHs with each other. In addition, the supporting plate for receiving the conductive members may be interposed between the first and second MPHs. The screws are then inserted into the first and second MPHs and the supporting plate.

In step S740, the needles, which make contact with the outer terminal of the object, are formed on the second conductive traces, respectively.

Particularly, referring to FIG. 10, in step S750, a pattern is formed on a sacrificial substrate. Here, the pattern may include a photoresist pattern formed by a photolithography process. That is, a photoresist film is formed on the sacrificial substrate. The photoresist film is then exposed and developed to form the photoresist pattern.

In step S760, the sacrificial substrate is partially etched using the pattern as an etching mask to form recesses at a surface portion of the sacrificial substrate. Here, each of the recesses has a shape corresponding to that of each of the needles.

In step S770, the recesses are filled with a conductive material to form the needles in the recesses. An example of the conductive material includes a metal such as copper, aluminum, etc.

In step S780, the needles are then bonded to the second traces.

In step S790, the sacrificial substrate is then removed to complete the probe card including the first and second MPHs and the needles.

### INDUSTRIAL APPLICABILITY

According to the present invention, the MPH includes the two detachable heads. Thus, when the object is changed into a new one, only the second MPH may be replaced with a new one. Thus, time and costs for manufacturing the probe card may be reduced.

Further, since only the second MPH is replaced with a new one and the first MPH having good flatness is still used, the probe card having the multi-layered structure may have good flatness.

Having described the preferred embodiments of the present invention, it is noted that modifications and variations can be made by persons skilled in the art in light of the above teachings. It is therefore to be understood that changes may be made in the particular embodiment of the present invention disclosed which is within the scope and the spirit of the invention outlined by the appended claims.

1. A probe card comprising:
a first micro probe head (MPH) including first conductive traces into which a test signal for testing an object having outer terminals is inputted;
a second MPH detachably combined with the first MPH, the second MPH including second conductive traces that are electrically connected to the first conductive traces and correspond to the outer terminal; and
needles electrically connected to the second conductive traces, the needles making contact with the outer terminals.

2. The probe card of claim 1, further comprising conductive members interposed between the first and second conductive traces to electrically connect the first and second traces to each other.

3. The probe card of claim 2, wherein the conductive members comprise an elastic metal.

4. The probe card of claim 3, wherein the elastic metal comprises solder.

5. The probe card of claim 2, further comprising a supporting plate interposed between the first and second MPHs to receive the conductive members.

6. The probe card of claim 1, further comprising a combing member inserted into the first and second MPHs to detachably combine the first and second MPHs with each other.

7. The probe card of claim 6, wherein the combining member comprises three screws vertically inserted into three edge portions of the first and second MPHs to adjust a horizontal level of the first and second MPHs.

8. A method of manufacturing a probe card, comprising:
preparing a first MPH that includes first conductive traces into which a test signal for testing an object having outer terminals is inputted;
preparing a second MPH that includes second conductive traces corresponding to the outer terminals;
detachably combining the second MPH with the first MPH to electrically connect the first conductive traces to the second conductive traces; and
forming needles, which make contact with the outer terminals, on the second conductive traces.

9. The method of claim 8, wherein combining the first and second MPHs comprises electrically connecting the first and second conductive traces using conductive members.

10. The method of claim 8, wherein the first and second MPHs are combined with each other using at least one screw.

11. The method of claim 8, wherein forming the needles comprises:
forming a pattern on a sacrificial substrate;
partially etching the sacrificial substrate using the pattern as an etching mask to form recesses, which have a shape corresponding to that of the needles, at a surface portion of the sacrificial substrate;
filling the recesses with a conductive material to form the needles in the recesses;
bonding the needles to the second conductive traces, respectively; and
removing the sacrificial substrate.
